(19) United States
(12) Patent Application Publication
(10) Pub. No.: US 2011/0075375 A1
(43) Pub. Date: Mar. 31, 2011

(54) TUNER MODULE CAPABLE OF PREVENTING A HEAT CONDUCTIVE SHEET FROM ARISING

(75) Inventors: Naoto KONDO, Tokyo (JP); Takumi Suzuki, Tokyo (JP)

(73) Assignee: MITSUMI ELECTRIC CO., LTD., Tokyo (JP)

(21) Appl. No.: 12/887,709

(22) Filed: Sep. 22, 2010

(30) Foreign Application Priority Data
Sep. 29, 2009 (JP) 2009-223791

(51) Int. Cl. H05K 7/20

(52) U.S. Cl. 361/707

(57) ABSTRACT

A tuner module includes a circuit board, an electronic component, mounted on the circuit board, for demodulating a high frequency reception signal received from an antenna unit to produce a speech signal, a metal case accommodating the circuit board and the electronic component therein, and a heat conductive sheet, disposed between the electronic component and the metal case, made of an elastic body. The heat conductive sheet has dimensions which are substantially equal to or slightly lower than outer dimensions of the electronic component. The metal case has at least one slit-shaped hole which is formed along an outer shape of the electronic component.

This application is based upon and claims the benefit to priority from Japanese patent application No. 2009-223791, filed on Sep. 29, 2009, the disclosure of which is incorporated herein in its entirety by reference.

### BACKGROUND OF THE INVENTION

This invention relates to a tuner module for a radio receiver and, in particular, relates to a tuner module suitable for an automobile digital radio receiver capable of listening to digital radio broadcasting by receiving radio waves from an artificial satellite (hereinafter referred to as “satellite waves”) or radio waves on the ground (hereinafter referred to as “terrestrial waves”).

SDARS (Satellite Digital Audio Radio Service) is a radio service according to a digital radio broadcasting using artificial satellites (which will called “SDARS satellites” hereinafter) in the United States of America. That is, in recent years, a digital radio receiver, which receives the satellite wave from the SDARS satellites or the terrestrial wave so as to listen to the digital radio broadcasting, has been developed and is put to practical use in the United States of America. Specifically, two broadcasting stations called XM and Sirius provide radio programs on 250 or more channels in total. The digital radio receiver is generally mounted on a mobile object (a mobile station) such as an automobile and is adapted to receive a radio wave (a SDARS signal) having a frequency of about 2.3 gigahertz (GHz) as a received wave to listen to the digital radio broadcasting. In other words, the digital radio receiver is a radio receiver capable of listening to mobile broadcasting. Inasmuch as the received wave (the SDARS signal) has the frequency of about 2.3 GHz, a reception wavelength (resonance frequency) λ thereof is equal to about 128 mm. It is noted here that the terrestrial wave is a radio wave obtained by receiving the satellite wave at a ground station, slightly shifting the frequency of the satellite wave, and retransmitting the linear polarized wave. Thus, the terrestrial wave is the linear polarized wave exhibiting linear polarization while the satellite wave is a circular polarized wave exhibiting circular polarization. As an antenna for SDARS, a planer antenna such as a patch antennas is used.

An XM satellite radio antenna apparatus normally serves to receive circular polarized radio waves from two stationary satellites and, in an insensitive zone of the circular polarized waves, receives a radio wave by using a terrestrial linear polarization portion of the radio antenna apparatus. On the other hand, a Sirius satellite radio antenna apparatus normally serves to receive circular polarized radio waves from three orbiting satellites (synchronous type) and, in the insensitive zone, receives a radio wave by a terrestrial linear polarization portion of the radio antenna apparatus.

As described above, the radio wave (the SDARS signal) having the frequency of about 2.3 GHz is used in the digital radio broadcasting. Therefore, an antenna for receiving the SDARS signal may be almost located outside as known in the art. If the digital radio receiver is mounted in the mobile object (the mobile station) such as the automobile, the antenna unit may be almost attached to a roof of the mobile object (the mobile station).

Such as an antenna for the automobile and a receiver body (a head unit) put inside a room of the automobile are electrically connected to each other through an extension cable. The head unit serves as an external device.

A receiving system of the type described for receiving the satellite wave or the terrestrial wave includes an antenna portion (an antenna unit) and a tuner portion (a satellite digital radio reception module). The antenna portion (the antenna unit) receives the satellite wave or the terrestrial wave to produce a reception signal having a high frequency. The turner portion (the satellite digital radio reception module) demodulates the reception signal into a speech signal.

Normally, electronic components constituting the tuner are mounted on a printed wiring board and placed in a metal case also serving as a shield (see, e.g. Japanese Unexamined Patent Application Publication (JP-A) No, H06-209268).

Referring to FIG. 1, the description will be made about one example of structure of the satellite digital radio reception module. The satellite digital radio reception module comprises an antenna 101, a tuner section 102, a signal demodulation section 103, a channel demodulation section 104, a sound decoder 105, a data decoder 106, a control section 107, and an operating section 108 (see, e.g. Japanese Unexamined Patent Application Publication (JP-A) No. 2002-344335).

In the meantime, the electronic components constituting the tuner include IC components from which heat generates. In order to favorably radiate heat generated from the IC components to outside, a tuner module in which a heat conductive sheet (a heat transfer sheet) is provided between an electronic component (the IC component) and a metal case is suggested (see, e.g. U.S. Pat. No. 7,778,044). The heat conductive sheet (the heat transfer sheet) is, for example, made of silicone rubber having high thermal conductivity.

On the other hand, in order to confirm the presence or absence of the heat conductive sheet (the heat transfer sheet) or to inhibit to forget about sticking up the heat conductive sheet (the heat transfer sheet), boring of a sight hole in the metal case has been carried out. For example, Japanese Unexamined Patent Application Publication (JP-A) No. 2006-330587 discloses a display device which is capable of suppressing positional displacement when the heat transfer sheet is attached to a heat dissipation member and of easily confirming the present of absent of the heat transfer sheet. In JP-A No. 2006-330587, as an embodiment, round holes are provided as penetration parts formed at positions corresponding to diagonal opposite corners of the heat transfer sheet in the heat dissipation member.

As described above, the silicone rubber having high thermal conductivity is used as the heat conductive sheet (the heat transfer sheet). On the other hand, when the heat conductive sheet (the heat transfer sheet) is disposed between the electronic component (the IC component) and the metal case, the heat conductive sheet (the heat transfer sheet) is sandwiched between the metal case and the electronic component (the IC component) with it pressed therebetween. Inasmuch as the silicone rubber is made of an elastic body, the heat conductive sheet (the heat transfer sheet) gets longer by the above-mentioned pressing.

As a result, when the penetration parts (the round holes) are provided at the positions corresponding to the diagonal opposite corners of the heat transfer sheet in the heat dissipation member, as described in the above-mentioned JP-A No. 2006-330587, there is in danger of arising the heat conductive sheet (the heat transfer sheet) from the penetration parts (the round holes).

### SUMMARY OF THE INVENTION

It is therefore an object of this invention to provide a tuner module which is capable of preventing a heat conductive sheet from arising and of easily confirming the presence or absence of the heat conductive sheet.

It is another objet of this invention to provide a tuner module which is capable of preventing positional displacement of the heat conductive sheet on attaching the heat conductive sheet to a metal case.

Other objects of this invention will become clear as the description proceed.

On describing the gist of an exemplary aspect of this invention, a tuner module includes a circuit board, an electronic component, mounted on the circuit board, for demodulating a high frequency reception signal received from an antenna unit to produce a speech signal, a metal case accommodating the circuit board and the electronic component therein, and a heat conductive sheet disposed between the electronic component and the metal case. The heat conductive sheet is made of an elastic body. According to this invention, the heat conductive sheet has dimensions which are substantially equal to or slightly lower than outer dimensions of the electronic component, and the metal case has at least one slit-shaped hole which is formed along an outer shape of the electronic component.

### BRIEF DESCRIPTION OF THE DRAWINGS

FIG. 1 is a block diagram showing the structure of a satellite digital radio receiver as one example of a conventional digital radio receiver;

FIG. 2 is a plan view showing a tuner module according to an exemplary embodiment of this invention:

FIG. 3 is a front cross sectional view of the tuner module illustrated in FIG. 2;

FIG. 4 is an expanded sectional view of the tuner module that shows a main part of FIG. 3 being enlarged; and

FIGS. 5A and 5B are diagrams as seen from the top and bottom sides of a printed wiring board (a circuit board) mounted with electronic components constituting the tuner module shown in FIG. 2.

### DESCRIPTION OF THE PREFERRED EMBODIMENT

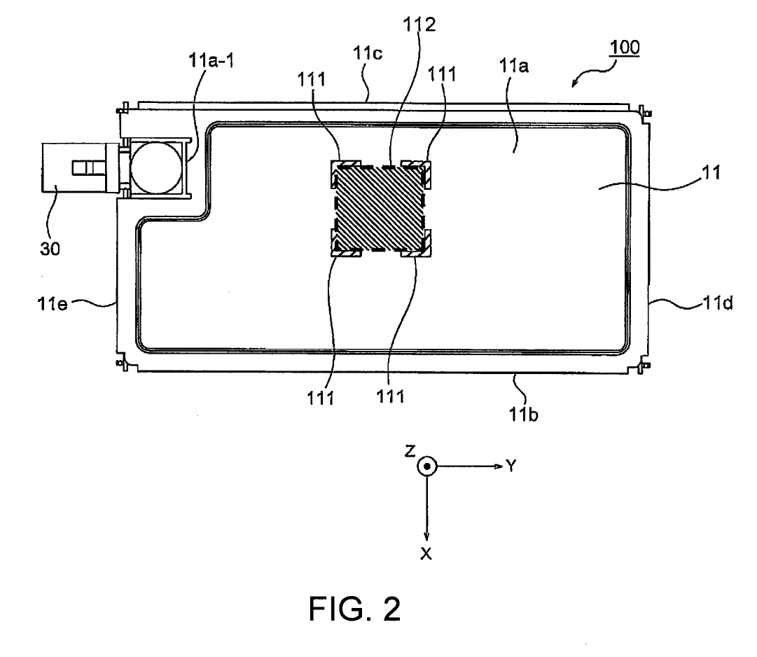

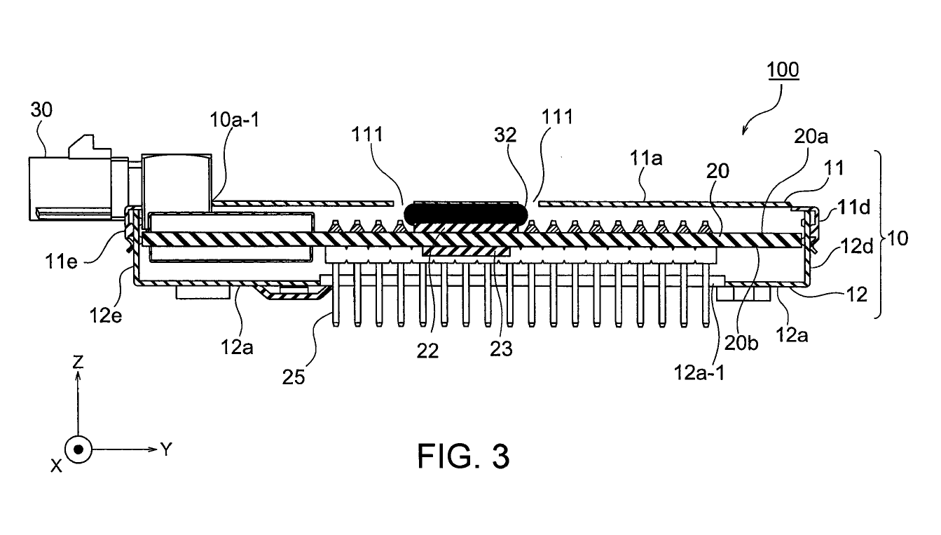

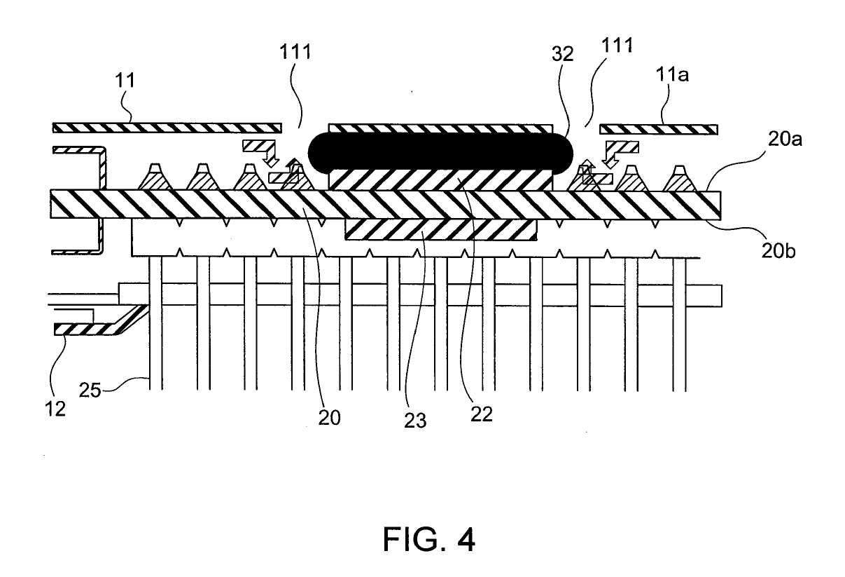

Referring to FIGS. 2 through 4, the description will proceed to a tuner module 100 according to an exemplary embodiment of this invention. FIG. 2 is a plan view of the tuner module 100. FIG. 3 is a front cross sectional view of the tuner module 100. FIG. 4 is an expanded sectional view of the tuner module 100 that shows a main part of FIG. 3 being enlarged.

Herein, in the manner shown in FIGS. 2 and 3, an orthogonal coordinate system (X, Y, Z) is used. In a state illustrated in FIGS. 2 and 3, in the orthogonal coordinate system (X, Y, Z), an X-axis direction is a fore-and-aft direction (a depth direction), a Y-axis direction is a left-and-right direction (a lateral direction), and a Z-axis direction is an up-and-down direction (a height direction).

The illustrated tuner module 100 shows an (inverted mounted) example where it is transversely mounted on a main surface of a main board of a car stereo. However, this invention may be, of course, applicable to a (portrait mounted) case where the tuner module is longitudinally mounted on the main surface of the main board of the car stereo.

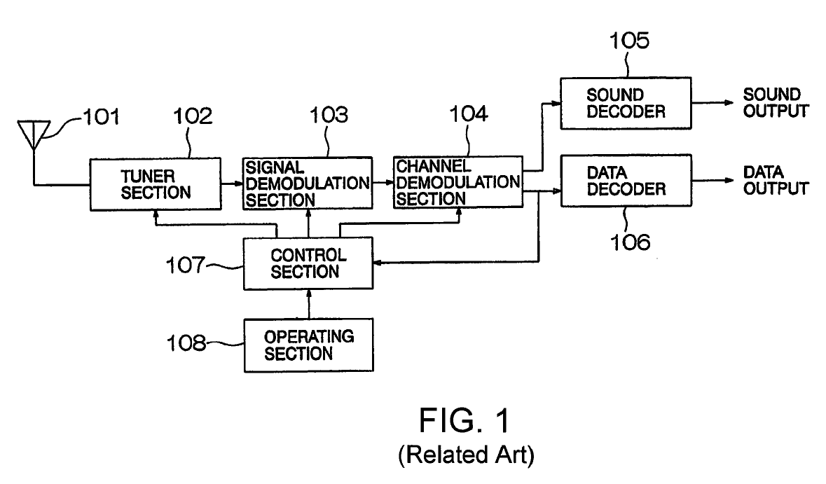

Hereinbelow, description will be given of a case where this invention is applied particularly to an automobile digital radio receiver among satellite digital radio receivers, one example of which was explained with reference to FIG. 1.

FIGS. 2 and 3 show the case where, among constituent components of the automobile digital radio receiver, a tuner section, a demodulation section, a sound decoder section, a data decoder section, and a controller for controlling them are mounted on a single printed wiring board (a circuit board) 20, and this printed wiring board (the circuit board) 20 is placed in a metal case, which will later be described. Herein, this structure is called a “tuner module”.

The tuner module 100 comprises the metal case (a sheet-metal case; a shielded case) 10 which will later be described and the printed wiring board (the circuit board) 20. The metal case (the sheet-metal case; the shielded case) 10 comprises a first case 11 and a second case 12. Inasmuch as the tuner module 100 is a type where it is transversely mounted on the main surface of the main board of the car stereo that extends in a horizontal direction, the first case 11 is called an upper case while the second case 12 is called a lower case.

For reference sake, in a case where the tuner module 100 is longitudinally mounted on the main surface of the main board, the first and the second cases 11 and 12 are used as front and rear cases, respectively.

In the example being illustrated, each of the upper case 11 and the lower case 12 is made by bending a metal plate.

The upper case 11 substantially has a box shape without a bottom plate portion (a lower plate portion). Specifically, the upper case 11 has an upper plate portion 11a which substantially extends in parallel with an X-Y plane defined by the fore-and-aft direction X and the left-and-right direction Y. The upper case 11 further has a front plate portion 11b and a rear plate portion (a back plate portion) 11c which are opposite to each other in the fore-and-aft direction X, and has a right plate portion 11d and a left plate portion 11e which are opposite to each other in the left-and-right direction Y.

On the other hand, the lower case 12 substantially has a box shape without an upper plate portion. Specifically, the lower case 12 has a bottom plate portion (a lower plate portion) 12a which substantially extends in parallel with the X-Y plane defined by the fore-and-aft direction X and the left-and-right direction Y. The lower case 12 further has a front plate portion (not shown) and a rear plate portion (not shown) which are opposite to each other in the fore-and-aft direction X, and has a right plate portion 12d and a left plate portion 12e which are opposite to each other in the left-and-right direction Y.

The printed wiring board (the circuit board) 20 is placed in a space between the upper and lower cases 11 and 12, except its portions necessary for electrical connection to the exterior (that will later be described), so as to be shielded. In the example being illustrated, the printed wiring board (the circuit board) 20 is fixed with it sandwiched in the lower case 12.

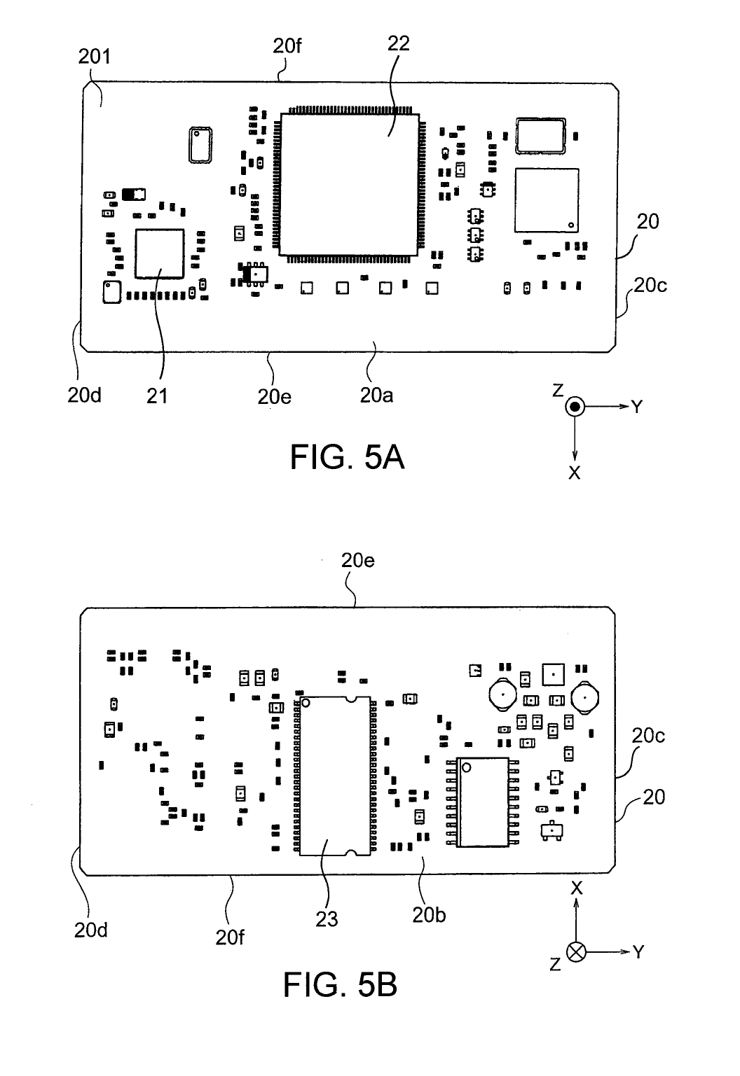

FIGS. 5A and 5B are views showing the printed wiring board (the circuit board) 20 on which circuit components (electronic components) making up the tuner module 100 are mounted. FIG. 5A is a plan view of the printed wiring board (the circuit board) 20 where it is seen from the top side thereof while FIG. 5B is a bottom view of the printed wiring board (the circuit board) 20 where it is seen from the bottom side thereof.

The printed wiring board (the circuit board) 20 has a substantial rectangular plate shape which extends in parallel with the X-Y plane defined by the fore-and-aft direction X and the left-and-right direction Y. The printed wiring board (the circuit board) 20 has an upper surface 20a and a lower surface (a bottom surface) 20b which are opposite to each other in the up-and-down direction Z. The printed wiring board (the circuit board) 20 has a right side 20c and a left side 20d which are opposite to each other in the left-and-right direction Y, and has a front side 20e and a rear side (a back side) 20f which are opposite to each other in the fore-and-aft direction X. The upper case 11 is disposed at the upper surface 20a side of the printed wiring board (the circuit board) 20 while the lower case 12 is disposed at the lower surface (the bottom surface) 20b side thereof.

As shown in FIG. 5A, a first IC component 21 and a second IC component 22 are mounted on the upper surface 20a of the printed wiring board (the circuit board) 20. The first IC component 21 serves as a main constituent component of the tuner section while the second IC component 22 serves as a main constituent component of the demodulation section. On the other hand, as shown in FIG. 5B, a third IC component 23 is mounted on the lower surface (the bottom surface) 20b of the printed wiring board (the circuit board) 20. The third IC component 23 serves as a main constituent component of a memory.

That is, on the printed wiring board (the circuit board) 20, the first through the third IC components 21 to 23 are mounted as electronic components for demodulating a high frequency reception signal received from an antenna unit (not shown) to produce a speech signal. The second IC component 22 has a rectangular parallelepiped shape, as apparent from FIG. 5A. The third IC component 22 also has a rectangular parallelepiped shape, as apparent from FIG. 5B.

As shown in FIGS. 3 and 4, a heat conductive sheet 32 is bonded to the top surface (herein, the whole top surface) of the second IC component 22 or to the inner surface of the metal case 10 (an inner wall of the upper plate portion 11a of the upper lower case 11). The heat conductive sheet 32 is made of an elastic body. For achieving better heat conduction, the heat conductive sheet 32 is placed in tight surface contact with the second IC component 22 and the inner wall of the upper plate portion 11a of the upper case 11. As a material of the heat conductive sheet 32, there is cited, for example, silicone rubber, acrylic rubber, graphite, or the like.

Although illustration is omitted, a heat conductive sheet is bonded to the top surface (herein, the whole top surface) of the third IC component 23 or the inner surface of the metal case 10 (an inner wall of the bottom plate portion 12a of the lower case 12).

FIGS. 3 and 4 show a state where the heat conductive sheet 32 is sandwiched between the metal case 10 (the upper case 11) and the second IC component (an electronic component) 22 with it pressed therebetween. Accordingly, in the state of FIGS. 3 and 4, the heat conductive sheet 32 gets longer by the above-mentioned press.

It should be noted that the heat conductive sheet 32 has dimensions which are substantially equal to or slightly lower than outer dimensions of the second IC component (the electronic component) 22 in a state prior to the above-mentioned press.

In addition, it should be also noted that the heat conductive sheet (not shown) bonded to the top surface of the third IC component 23 has dimensions which are substantially equal to or slightly lower than outer dimensions of the third IC component (the electronic component) 23 in a state prior to the above-mentioned press.

As shown in FIG. 3, on the lower surface (the bottom surface) 20b of the printed wiring board (the circuit board) 20, connector pins 25 are mounted at a side of the rear side (the back side) 20f. The connector pins 25 are inserted into a main board (not shown). The bottom plate portion (the lower plate portion) 12a of the lower case 12 has a rectangular connector notch portion 12a-1 at a position of the back plate portion that corresponds to a set position of the connector pins 25.

As shown in FIG. 5A, the printed wiring board (the circuit board) 20 has, at a left-back corner portion, an RF input portion 201 for inputting the reception signal having a high frequency (RF) from the antenna unit (not shown). On the other hand, as shown in FIG. 3, the upper plate portion 11a of the upper case 11 has a rectangular notch portion 11a-1 at a position of the left plate portion 11e that corresponds to the RF input portion 201. An RE connector 30 is connected to the RF input portion 201.

The RF connector 30 is mounted to the tuner module 100 with it protruded in a left direction toward a left lower place of the tuner module 100 (e.g., at a position close to the left plate portion 11e).

As shown in FIG. 2, the upper plate portion 11a of the upper case 11 of the metal case 10 has four slit-shaped holes 111 which are formed along an outer shape of the second IC component (the electronic component) 22. The four slit-shaped holes 111 are disposed at positions corresponding to corner portions of the second IC component (the electronic component) 22 so that a region 112 enclosed by the four slit-shaped holes 111 are substantially equal to that of the second IC component (the electronic component) 22. Each slit-shaped hole 111 has an L shape.

In other words, as shown in FIG. 4, the four L-shaped slit-shaped holes 111 are formed to the metal case 10 (the upper case 11) along the outer shape of the second IC component (the electronic component) 22 so that it allows repelling force of the heat conductive sheet 32 to disperse to the outer regions of the second IC component (the electronic component) 22 mounted on the printed wiring board (the circuit board) 20. Therefore, the repelling force of the heat conductive sheet 32 disperses in a direction depicted at an arrow, as shown in FIG. 4.

Inasmuch as the four L-shaped slit-shaped holes 111 are formed to the metal case 10 along the outer shape of the electronic component 22 and the region 112 enclosed by the four L-shaped slit-shaped holes 111 is substantially equal to that of the outer dimensions of the electronic component 22 in the exemplary embodiment, it is possible to prevent the heat conductive sheet 32 from arising from the slit-shaped holes 111 by pressing of the metal case 10. This is because, on non-pressing, the heat conductive sheet 32 has dimensions which are substantially equal to or slightly lower than outer dimensions of the electronic component 22. On the other hand, inasmuch as the heat conductive sheet 32 gets longer by the above-mentioned pressing of the metal sheet 10 as shown in FIG. 4, it is possible to easily confirm the presence or absence of the heat conductive sheet 32 via the slit-shaped holes 111 visually. Accordingly, it is possible to inhibit to forget about sticking up the heat conductive sheet 32 even after assembling of the tuner module 100.

Furthermore, inasmuch as the four L-shaped slit-shaped holes 111 are disposed to the positions corresponding to the corner portions of the electronic component 22 and the region 112 enclosed by the four L-shaped slit-shaped holes 111 are substantially equal to that of the outer dimensions of the second IC component (the electronic component) 22, it is possible to minimize displacement of affixation positions in any direction of left-and-right, fore-and-aft, and a slanting on bonding the heat conductive sheet 32 to the inner wall of the upper plate portion 11a of the metal case 10 (the upper case 11). It is therefore to prevent positional displacement of the heat conductive sheet 32 with respect to the electronic component 22.

Likewise, although illustration is omitted, the bottom plate portion 12a of the lower case 12 of the metal case 10 has four slit-shaped holes which are formed along an outer shape of the third IC component (electronic component) 23. These four slit-shaped holes are disposed to positions corresponding to corner portions of the third IC component (electronic component) 23. Each slit-shaped hole has an L shape.

In the tuner module 100 according to the exemplary aspect of this invention, the metal case 10 desirably may have at least two slit-shaped holes 111 at positions which are opposite to each other. The electronic component 22 may have a rectangular parallelepiped shape. In this event, the slit-shaped holes preferably may be disposed at positions corresponding to corners of the electronic component 22. The slit-shaped holes 111 may be equal in number to four. Each of the slit-shaped holes 111 desirably may have an L shape. The heat conductive sheet 32 preferably may be made of silicone rubber.

An exemplary advantage according to the invention is that it is possible to prevent the heat conductive sheet from arising and to easily confirm the presence or absence of the heat conductive sheet. This is because, the heat conductive sheet disposed between the electronic component and the metal case has dimensions which are substantially equal to or slightly lower than outer dimensions of the electronic component, and the metal case has at least one slit-shaped hole which is formed along an outer shape of the electronic component.

While this invention has been particularly shown and described with the reference to the exemplary embodiment thereof, the invention is not limited to the embodiment. It will be understood by those of ordinary skill in the art that various changes in form and details may be therein without departing from the sprit and scope of the present invention as defined by the claims. For example, although the metal case has the four L-shaped slit-shaped holes which are formed along the outer shape of the electronic component in the above-mentioned exemplary embodiment, as a matter of course, the shape and the number of the slit-shaped holes are not limited to them. For instance, the metal case may have at least two slit-shaped holes at positions opposite to each other. Each slit-shaped hole may have a straight-line shape. If it just may inhibit to forget about sticking up the heat conductive sheet, the metal case may have only one slit-shaped hole. In addition, although the slit-shaped holes are disposed to the positions corresponding to the corners of the electronic component in the above-mentioned exemplary embodiment, as a matter of course, the positions where the slit-shaped holes are disposed are not limited to this. At any rate, the metal case may have at least one slit-shaped hole along the outer shape of the electronic component.

This invention is particularly suitable for a tuner module in an automobile digital radio receiver requiring miniaturization, but is of course applicable to the whole range of radio receivers that require heat radiation because of using electronic components.

What is claimed is:

1. A tuner module comprising:
a circuit board;
an electronic component mounted on said circuit board, said electronic component demodulating a high frequency reception signal received from an antenna unit to produce a speech signal;
a metal case accommodating said circuit board and said electronic component therein; and
a heat conductive sheet disposed between said electronic component and said metal case, said heat conductive sheet being made of an elastic body,
wherein said heat conductive sheet has dimensions which are substantially equal to or slightly lower than outer dimensions of said electronic component, and
wherein said metal case has at least one slit-shaped hole which is formed along an outer shape of said electronic component.

2. The tuner module according to claim 1, wherein said metal case has at least two slit-shaped holes at positions which are opposite to each other.

3. The tuner module according to claim 2, wherein said electronic component has a rectangular parallelepiped shape,
wherein said slit-shaped holes are disposed at positions corresponding to corners of said electronic component.

4. The tuner module according to claim 3, wherein said slit-shaped holes are equal in number to four.

5. The tuner module according to claim 3, wherein each of said slit-shaped holes has an L shape.

6. The tuner module according to claim 1, wherein said heat conductive sheet is made of silicone rubber.

7. The tuner module according to claim 1, wherein said metal case comprises first and second cases, and
wherein said circuit board is sandwiched between said first and second cases such that said circuit board is provided in a space between said first and second cases, except for portions of the circuit board necessary for electrical connection to outside of the metal case.

8. The tuner module according to claim 7, wherein in said metal case, said heat conductive sheet is provided between said electronic component and said first case so as to be in contact with said electronic component and said first case.

9. The tuner module according to claim 1, wherein said heat conductive sheet is bonded to said electronic component so as to be provided between and in contact with said electronic component and said metal case.

10. The tuner module according to claim 1, wherein said heat conductive sheet is bonded to an inner wall of said metal case so as to be provided between and in contact with said electronic component and said metal case.

11. The tuner module according to claim 1, wherein the heat conductive sheet is made of one of acrylic rubber and graphite.

12. The tuner module according to claim 1, wherein said metal case comprises upper and lower cases, and
wherein said circuit board is sandwiched between said upper and lower cases such that said circuit board is provided in a space between said upper and lower cases, except for portions of the circuit board necessary for electrical connection to outside of the metal case.

13. The tuner module according to claim 12, wherein in said metal case, said heat conductive sheet is provided between said electronic component and said upper case so as to be in contact with said electronic component and said upper case.
